(19) United States
(12) Patent Application Publication
(10) Pub. No.: US 2009/0278534 A1
(43) Pub. Date: Nov. 12, 2009

(54) MAGNETIC SENSOR DEVICE FOR AND A METHOD OF SENSING MAGNETIC PARTICLES

(75) Inventor: Josephus Arnoldus Henricus Maria Kahlman, Tilburg (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/305,385

(22) PCT Filed: Jun. 18, 2007
(86) PCT No.: PCT/IB07/52325

§ 371 Date: Dec. 18, 2008

(30) Foreign Application Priority Data
Jun. 28, 2006 (EP) 06116227.7

(51) Int. Cl. G01R 33/09

(52) U.S. Cl. 324/252

(57) ABSTRACT

A magnetic sensor device (300) for sensing magnetic particles (15), the magnetic sensor device (300) comprising a magnetic field generator unit (12) adapted for generating a plurality of different magnetic field configurations assigned to a plurality of different magnetic excitation states of the magnetic particles (15), a sensing unit (11) adapted for sensing a plurality of detection signals influenced by the magnetic particles (15) in the different magnetic field configurations, and a combining unit (30) adapted for combining the plurality of signals to thereby derive information indicative of the presence of the magnetic particles (15).

### FIELD OF THE INVENTION

The invention relates to a magnetic sensor device for sensing magnetic particles.

The invention further relates to a method of sensing magnetic particles.

Moreover, the invention relates to a program element.

Further, the invention relates to a computer-readable medium.

### BACKGROUND OF THE INVENTION

A biosensor may be a device for the detection of an analyte that combines a biological component with a physicochemical or physical detector component.

Magnetic biosensors may use the Giant Magnetoresistance Effect (GMR) for detecting biological molecules being magnetic or being labeled with magnetic beads.

In the following, biosensors will be explained which may use the Giant Magnetoresistance Effect.

WO 2005/010542 discloses the detection or determination of the presence of magnetic particles using an integrated or on-chip magnetic sensor element. The device may be used for magnetic detection of binding of biological molecules on a micro-array or biochip. Particularly, WO 2005/010542 discloses a magnetic sensor device for determining the presence of at least one magnetic particle and comprises a magnetic sensor element on a substrate, a magnetic field generator for generating an AC magnetic field, a sensor circuit comprising the magnetic sensor element for sensing a magnetic property of the at least one magnetic particle which magnetic property is related to the AC magnetic field, wherein the magnetic field generator is integrated on the substrate and is arranged to operate at a frequency of 100 Hz or above.

WO 2005/010543 discloses a magnetic sensor device comprising a magnetic sensor element on a substrate and at least one magnetic field generator for generating a magnetic field on the substrate, wherein crosstalk suppression means are present for suppressing crosstalk between the magnetic sensor element and the at least one magnetic field generator.

WO 2005/111596 discloses distinguishing a specific binding from a less specific binding between at least one magnetic nanoparticle and a surface of another entity by applying a magnetic field and detecting a physical parameter relating to magnetic nanoparticle rotational or motional freedom while the magnetic nanoparticle is attached to the surface. The sensor combines the detection of magnetic particles or labels and determination of the binding quality and the properties of magnetic particles or labels which are bound to the surface of another entity.

However, the sensitivity of such a sensor may still be insufficient under undesired circumstances.

### OBJECT AND SUMMARY OF THE INVENTION

It is an object of the invention to provide a sensor with a sufficient sensitivity, stability and accuracy.

In order to achieve the object defined above, a magnetic sensor device for sensing magnetic particles, a method of sensing magnetic particles, a program element, and a computer-readable medium according to the independent claims are provided.

According to an exemplary embodiment of the invention, a magnetic sensor device for sensing magnetic particles is provided, the magnetic sensor device comprising a magnetic field generator unit (for instance one or more wires to which an electric current is applied) adapted for generating a plurality of different magnetic field configurations (for instance by applying different electric current sequences to respective ones of the wires) assigned to a plurality of different magnetic excitation states of the magnetic particles (for instance, different electric current sequences applied to respective ones of the wires may magnetically influence a magnetic particle in a different manner, for instance with regard to amplitude and/or direction of the field influencing the magnetic particle), a sensing unit (for instance a GMR sensor) adapted for sensing a plurality of detection signals influenced by the magnetic particles in the different magnetic field configurations, and a combining unit (for instance a microprocessor or a CPU having processing capabilities and being capable of evaluating the individual sensor signals together in accordance with an appropriate calculation scheme) adapted for combining the plurality of signals to thereby derive information indicative of the presence of the magnetic particles (for instance for calculating a realistic gain value as a basis for a sensor result).

According to another exemplary embodiment of the invention, a method of sensing magnetic particles is provided, the method comprising generating a plurality of different magnetic field configurations assigned to a plurality of different magnetic excitation states of the magnetic particles, sensing a plurality of detection signals influenced by the magnetic particles in the different magnetic field configurations, and combining the plurality of signals to thereby derive information indicative of the presence of the magnetic particles.

According to still another exemplary embodiment of the invention, a program element is provided, which, when being executed by a processor, is adapted to control or carry out a method of sensing magnetic particles having the above mentioned features.

According to yet another exemplary embodiment of the invention, a computer-readable medium is provided, in which a computer program is stored which, when being executed by a processor, is adapted to control or carry out a method of sensing magnetic particles having the above mentioned features.

The electronic sensing scheme according to embodiments of the invention can be realized by a computer program, that is by software, or by using one or more special electronic optimization circuits, that is in hardware, or in hybrid form, that is by means of software components and hardware components.

According to an exemplary embodiment, a magnetic (bio)sensor device for sensing magnetic particles using the magnetic properties (for instance beads attached to biological molecules) may be operated in different operation states correlated with different magnetic field configurations (for instance generated by a plurality of wires located at different positions of such a sensor), thereby achieving gain stabilization for the (particularly GMR) sensor by measuring the signal to crosstalk relation. In other words, when detecting detection signals in the different magnetic field configurations, signal conditioning and signal processing may be performed in order to suppress effects which conventionally disturb the accuracy of the sensor.

According to an exemplary embodiment, such a gain stabilization for magnetic biosensors by measuring the signal to crosstalk relation may be obtained by performing magnetic particle imaging. For improving magnetic particle detection, the sensitivity and stability of the magnetic particle sensor may be enhanced. By alternating between multiple excitation states and combining detected signal, an average gain factor can be determined, thus improving accuracy.

Therefore, a magneto-resistive biochip may be provided having improved properties for biomolecular diagnostics in terms of sensitivity, specificity, integration, ease of use, and costs.

Exemplary embodiments of the invention may also suppress variations in the detection electronic, for instance fluctuating sense current, fluctuating excitation current, as everything is determined by the geometry of the sensor. Furthermore, exemplary embodiments of the invention provide a stabilizing method, as it may stabilize the overall detection gain using the situation at t=0 as a reference.

Conventionally, the sensitivity (for instance of a GMR sensor), and therefore the effective gain for the bio-measurement may be sensitive or non-controllable parameters like non-stochastic sensitivity variations due to magnetic instability in the sensor. This error cannot be removed easily by using a reference sensor or bridged structure. Other non-controllable parameters (or parameters which cannot be controlled easily) are externally applied magnetic fields, production tolerances, aging effects, temperature effects, and memory effects (for instance for magnetic actuation fields).

Furthermore, internal compensation techniques for magnetic and capacitive crosstalk may fail when the GMR sensitivity varies.

In the light of these recognitions, exemplary embodiments of the invention intend to stabilize the sensor gain during the actual biological measurement.

According to an exemplary embodiment of the invention, the gain of the sensor is measured during the actual biological measurement by continuously varying the relation between the internal (geometry) dependent magnetic crosstalk and the signal from the beads by switching between magnetic excitation states. Furthermore, it is possible to calculate a gain factor (s_{GMR}) from a combination of the observed sensor signals in said states. Said gain factor may be used in a feedback or in a feedforward (normalize) circuit to stabilize the biosensor detection gain.

For applying such a method, it may be not necessary to have detailed knowledge about the concentration of the beads near the sensor. It may be possible to suppress uncorrelated (for instance s_{GMR}) errors as well as correlated errors like temperature effects. For example, embodiments of the invention may be used on top of approaches of sensor multiplexing suppressing correlated gain factors.

The time between two gain measurements may be fast enough to follow the expected gain variations. Furthermore, the gain measurement time may be preferably short enough to avoid gain fluctuations between the excitation states during a gain measurement.

Alternatively, the excitation states are not applied in a time-multiplex mode (one after each other), but in a frequency multiplex mode. Then, the excitation states are measured simultaneously by using different excitation frequencies for each state. As a result, gain variations during the measurement affecting the result wrongly may be securely avoided because gain varies equally for each state, resulting in the average gain during the measurement time. This embodiment may have the advantage that the measuring time may be longer, which may increase the signal-to-noise ratio obtainable with this method.

Embodiments of the invention may be applied for a biosensor based on integrated excitation of super paramagnetic nanoparticles, but also the application in other magneto-resistive sensors like AMR or TMR is possible. Furthermore, embodiments can be applied to an external excitation method. Such an external excitation method is based on the application of a magnetic field externally to a substrate in which a sensor is integrated. However, it is also possible that sensor and the magnetic field generator unit are both integrated in and/or on a substrate.

For example, s_{GMR} may be measured in the same frequency range as the bead excitation. This is because of reasons of signal-to-noise ratio (to reduce the influence of 1/f noise, small current, small voltage) and to be consistent to the bead measurement.

Furthermore, exemplary embodiments of the invention may be applied to other magneto resistive sensor configurations, for instance to configurations with sensors having Wheatstone bridges or half-Wheatstone bridges, or to other amplifier and sensor current elements than explicitly described herein.

Beyond this, embodiments of the invention are applicable to any biochemical- or small molecule measurements in blood, saliva and other body fluids or fluids extracted from body tissue or for instance faeces.

Moreover, embodiments of the invention may be applied to the detection of magnetic beads as well as to the measurement of bead properties (like frequency dependence, relaxation time), and biochemical binding quality (like bead rotation).

Embodiments of the invention may suppress artifacts resulting from the fact that sensor gain or sensor sensitivity may fluctuate in an undesired manner due to geometry effects or the like. According to an exemplary embodiment, multiple measurements may be performed in various excitation states of the magnetic particles to be detected. This may allow to eliminate or reduce such artifacts by combining the results in a mathematical manner, by calculating gain values which are more accurate or meaningful. For instance, the various measurements may be assigned to different angles/orientations of the exciting entity and/or the detecting entity with regard to the magnetic particles.

For exciting the magnetic field generator (for instance the wires), there is essentially no limitation with regard to specific current profiles. It is possible to use sine waves and square waves, particularly at a frequency well above a crossover point of the (magnetic) 1/f noise from the sensor and its thermal noise, which may be around 100 kHz.

Next, further exemplary embodiments of the magnetic sensor device will be explained. However, these embodiments also apply for the method of sensing magnetic particles, for the program element, and for the computer-readable medium.

The magnetic field generator unit may be adapted for generating the plurality of different magnetic field configurations sequentially in time. According to such an embodiment, a first specific magnetic field configuration is adjusted (for instance activating one of two magnetic field generator elements, and deactivating the other one). After having measured detection signals in this operation state, another magnetic field configuration may be adjusted, for instance by deactivating the previously activated magnetic field generator element and by activating the previously deactivated one. By such a time-multiplex scheme, geometry effects or the like may be suppressed or eliminated.

Additionally or alternatively, the magnetic field generator unit may be adapted for generating the plurality of different magnetic field configurations by frequency multiplexing. By taking this measure, it is not necessary to apply the different magnetic field configurations one after the other, but to mix different frequency contributions at the same time. This may be advantageous in terms of measurement time and efficiency.

The combination unit may be adapted for averaging fluctuations of the sensor gain. The combination of the plurality of signals for deriving information indicative of the presence of the magnetic particles may be performed by a mathematical procedure. By calculating an average gain value, artifacts on the measurement may be efficiently suppressed.

The magnetic field generator may comprise a plurality of magnetic field generator elements. With such a plurality of (spatially separated and separately controllable) magnetic field generator elements, the different magnetic field configurations may be adjusted by performing a specific activation/deactivation scheme, thereby defining a spatial dependence of the magnetic fields and therefore of the detection signals.

The plurality of magnetic field generator elements may be activable individually or in a groupwise manner for generating a plurality of different magnetic field configurations. This may allow for implementing a simple scheme which is highly flexible and allows to adjust the magnetic field environment in any desired manner.

The sensing unit may be arranged symmetrically or asymmetrically with respect to the plurality of magnetic field generator elements. For instance, the sensing unit, like a GMR sensor, may be positioned in the centre of gravity between two magnetic field generator elements (for instance two magnetic wires) to which a current may be applied. By providing an asymmetric geometry in which the GMR sensor is not provided (exactly) in the centre of gravity of the two or more magnetic field generator elements, the spatial asymmetry may be mapped into an asymmetry of the detection signals, which, by the combination unit, may further allow to remove artifacts.

The plurality of magnetic field generators may have different dimensions. For instance, the (cross-section) sizes of magnetic wires through which a current may flow may vary for the different magnetic field generator elements, thereby involving a further asymmetry and therefore a further degree of freedom for manipulating the detection signal.

The magnetic sensor device may comprise a substrate in which at least a part of the plurality of magnetic field generator elements is integrated. Such a (for instance semiconductor) substrate may have the magnetic field generator elements monolithically integrated therein, wherein the layout of such an integrated circuit may allow to involve the desired asymmetry or spatial dependence of the magnetic field generator elements to perform the combining or averaging scheme.

The plurality of magnetic field generator elements integrated in the substrate may be arranged parallel to a main surface of the substrate. Above the substrate, the sample to be analyzed may be provided (for instance a fluidic sample). The surface of the substrate to which such a sample may be supplied may be denoted as the main surface of the substrate. Along a surface region of this main surface, the various magnetic field generator elements may be aligned one next to the other.

The plurality of magnetic field generator elements may be integrated in the substrate to be arranged vertically with respect to a main surface of the substrate. Therefore, a vertical stack of magnetic field generator elements, optionally combined with a horizontal alignment of a plurality of magnetic field generator elements may be provided. By taking this measure, an array of magnetic field generator elements may be provided allowing to adjust a large variety of magnetic field configurations.

The magnetic sensor device may be adapted in such a manner that a predetermined spatial dependence of the magnetic particles is adjustable above a main surface of the substrate. For instance, a half of the surface above the substrate may be free of magnetic particles, or any gradient may be applied along the surface. Therefore, a particle asymmetry may be adjusted which further allows to detect individual detection signals which, in combination, may allow to suppress gain artifacts. It may be advantageous to foresee a gradual decrease of a surface density of the beads as a function of the position. In a biosensor, magnetic beads may be immobilized via target molecules to specific antibodies deposited (for example inkjet printed) on the sensor surface. The antibody density may thus determine the bead binding density. During production of the sensor device, said density may be varied by varying the droplet geometry and its position with respect to the sensor.

The magnetic field sensor device may be adapted in such a manner that another part of the plurality of magnetic field generator elements is provided on (not in) a main surface of the substrate. Therefore, the magnetic field generator elements may not only be provided monolithically integrated within the substrate, but also on the surface of the substrate. For instance, a gold layer which is in many cases deposited on a substrate when manufacturing a biosensor, and which may be particularly provided on top of the main surface of the substrate, may be patterned in such a manner so as to serve as a further magnetic field generator element (for instance by carrying out an appropriate etching and lithography procedure).

The magnetic sensor device may further comprise a magnetic body influencing the plurality of magnetic field generator elements in a plurality of different magnetic field configurations. Such a magnetic body may be any structure provided on and/or in a substrate and having a value of the magnetic permeability μ larger than one. The provision of such a magnetic body may introduce a further asymmetry in the detector and therefore in the detection scheme, allowing to remove or suppress gain fluctuations. An example for such a magnetic body is any soft magnetic material located between the (GMR) sensor and the excitation wire(s).

The magnetic field generator unit may be adapted for generating a plurality of different magnetic field configurations differing with regard to the magnetic field direction. For example, in a first operation state, a magnetic field may be applied (for instance using an external instead of an internal magnetic field source) having a first direction in a portion of the device in which the beads are arranged. In a second operation state, the magnetic field provided externally may be tilted with respect to the first configuration, and two or more of such angular operation states may be applied sequentially to the magnetic sensor device.

The combination unit may be adapted for combining the plurality of signals to thereby stabilize a detection gain factor. Therefore, the signal-to-noise ratio may be improved and the accuracy may be increased.

The magnetic sensor device may comprise a switch unit adapted for switching between the plurality of different magnetic field configurations. The algorithm according to which the switch unit operates on the different magnetic field generator elements may be controlled by a control unit, like a CPU.

The sensing unit may be adapted for sensing the magnetic particles based on an effect of the group consisting of GMR, AMR, and TMR. Particularly, a magnetic field sensor device may make use of the Giant Magnetoresistance Effect (GMR) being a quantum mechanical effect observed in thin film structures composed of alternating (ferro)magnetic and non-magnetic metal layers. The effect manifests itself as a significant decrease in resistance from the zero-field state, when the magnetization of adjacent (ferro)magnetic layers are antiparallel due to a weak anti-ferromagnetic coupling between layers, to a lower level of resistance when the magnetization of the adjacent layers align due to an applied external field. The spin of the electrons of the nonmagnetic metal align parallel or antiparallel with an applied magnetic field in equal numbers, and therefore suffer less magnetic scattering when the magnetizations of the ferromagnetic layers are parallel. Examples for biosensors making use of the Giant Magnetoresistance Effect (GMR) are disclosed in WO 2005/010542 or WO 2005/010543.

The combination unit may be adapted for combining the plurality of signals to thereby derive information indicative of a quantity of the magnetic particles. In other words, the magnetic sensor device may have the goal to detect the concentration or amount of the particles, according to an exemplary embodiment, and not only the “digital” information whether they are present or absent. Other properties of the beads may be estimated as well.

The magnetic sensor device may be adapted for sensing magnetic beads attached to biological molecules. Such biological molecules may be proteins, DNA, genes, nucleic acids, polypeptides, hormones, antibodies, etc.

Therefore, the magnetic sensor device may be adapted as a magnetic biosensor device, that is to say as a biosensor device operating on a magnetic detection principle.

At least a part of the magnetic sensor device may be realized as a monolithically integrated circuit. Therefore, components of the magnetic sensor device may be monolithically integrated in a substrate, for instance a semiconductor substrate, particularly a silicon substrate. However, other semiconductor substrates are possible, like germanium, or any group III-group V semiconductor (like gallium arsenide or the like).

Next, further exemplary embodiments of the method of sensing magnetic particles will be explained. However, these embodiments also apply for the magnetic sensor device, for the program element and for the computer-readable medium.

The method may comprise determining calibration information prior to the generation, sensing and combining procedures. By calibrating the sensor, the detection signals and the different operation modes may become more meaningful, and artifacts related to individual properties of a specific magnetic sensor (for instance manufacture tolerances) may be efficiently suppressed.

Particularly, determining calibration information may comprise at least one of the group consisting of generating and sensing in the absence of magnetic particles, generating and sensing in the presence of sedimented magnetic particles, generating and sensing in the presence of immobilized magnetic particles, and generating and sensing under reference conditions. By taking such measures, parameters like α and β (as will be explained below in more detail) may be determined prior to performing an actual sensor measurement, thereby increasing accuracy.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 illustrates a magnetic sensor device according to an exemplary embodiment in a first operation state.

FIG. 2 illustrates the magnetic sensor device of FIG. 1 in a second operation state.

FIG. 3 illustrates a magnetic sensor device according to an exemplary embodiment of the invention.

FIG. 4 illustrates a magnetic sensor device according to an exemplary embodiment.

FIG. 5 illustrates a GMR resistance as a function of a magnetic field in the sensitive layer of a GMR stack.

FIG. 6 to FIG. 13 show magnetic sensor devices according to exemplary embodiments of the invention.

FIG. 14 to FIG. 17 show diagrams illustrating crosstalk and detection signal characteristic of magnetic sensor devices.

FIG. 18A to FIG. 21B show magnetic sensor devices according to exemplary embodiments of the invention.

### DESCRIPTION OF EMBODIMENTS

The illustration in the drawing is schematically. In different drawings, similar or identical elements are provided with the same reference signs.

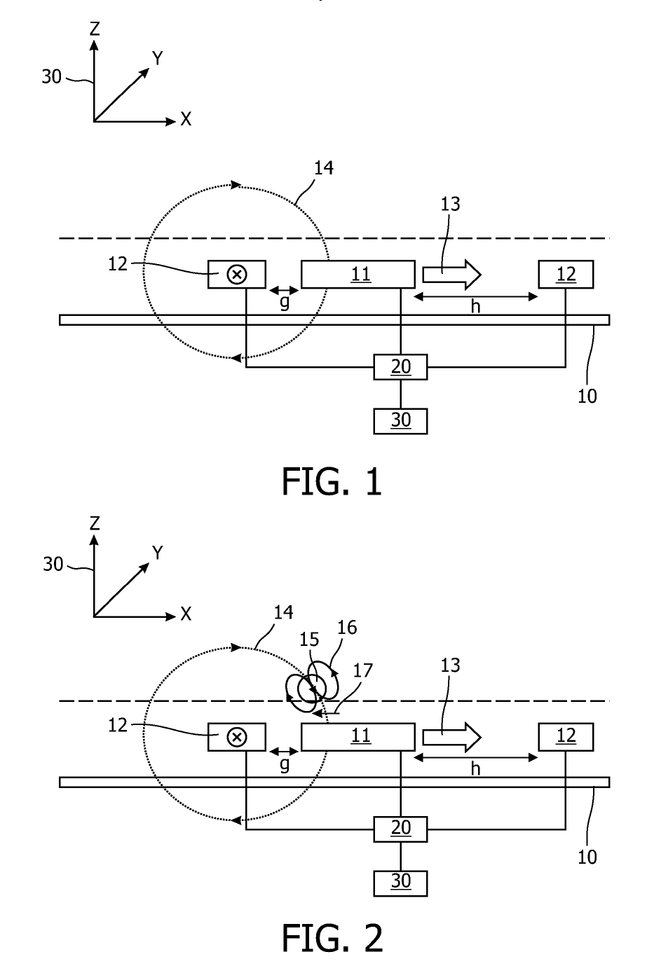

In a first embodiment the device according to the present invention is a biosensor and will be described with respect to FIG. 1 and FIG. 2. The biosensor detects magnetic particles in a sample such as a fluid, a liquid, a gas, a visco-elastic medium, a gel or a tissue sample. The magnetic particles can have small dimensions. With nano-particles are meant particles having at least one dimension ranging between 0.1 nm and 3000 nm, preferably between 3 nm and 500 nm, more preferred between 10 nm and 300 nm. The magnetic particles can acquire a magnetic moment due to an applied magnetic field (e.g. they can be paramagnetic). The magnetic particles can be a composite, e.g. consist of one or more small magnetic particles inside or attached to a non-magnetic material. As long as the particles generate a non-zero response to a modulated magnetic field, i.e. when they generate a magnetic susceptibility or permeability, they can be used.

The device may comprise a substrate 10 and a circuit e.g. an integrated circuit.

A measurement surface of the device is represented by the dotted line in FIG. 1 and FIG. 2. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following reference will be made to silicon processing as silicon semiconductors are commonly used, but the skilled person will appreciate that the present invention may be implemented based on other semiconductor material device(s) and that the skilled person can select suitable materials as equivalents of the dielectric and conductive materials described below.

The circuit may comprise a magneto-resistive sensor 11 as a sensor element and a magnetic field generator in the form of two separate conductors 12. The magneto-resistive sensor 11 may, for example, be a GMR, a AMR, Hall or a TMR type sensor. Moreover, the sensing unit 11 can be any suitable sensing unit 11 based on the detection of the magnetic properties of particles to be measured on or near to the sensor surface. Therefore, the sensing unit 11 is designable as a coil, magneto-resistive sensor, magneto-restrictive sensor, Hall sensor, planar Hall sensor, flux gate sensor, SQUID (Semiconductor Superconducting Quantum Interference Device), magnetic resonance sensor, or as another sensor actuated by a magnetic field.

The magneto-resistive sensor 11 may for example have an elongated, e.g. a long and narrow stripe geometry but is not limited to this geometry. Sensor 11 and conductors 12 may be positioned adjacent to each other within a close distance g and h, respectively. The distances g and h between sensor 11 and conductors 12 may for example be between 1 nm and 1 mm; e.g. 3 μm. The minimum distance is determined by the IC process.

In FIG. 1 and FIG. 2, a co-ordinate device is introduced to indicate that if the sensor device is positioned in the xy plane, the sensor 11 mainly detects the x-component of a magnetic field, i.e. the x-direction is the sensitive direction of the sensor 11. The arrow 13 in FIG. 1 and FIG. 2 indicates the sensitive x-direction of the magneto-resistive sensor 11 according to the present invention. Because the sensor 11 is hardly sensitive in a direction perpendicular to the plane of the sensor device, in the drawing the vertical direction or z-direction, a magnetic field 14, caused by a current flowing through the conductors 12, is not detected by the sensor 11 in absence of magnetic nano-particles 15. By applying current sequences to the conductors 12 in the absence of magnetic nano-particles 15, the sensor 11 signal may be calibrated. This calibration is preferably performed prior to any measurement.

When a magnetic material (this can e.g. be a magnetic ion, molecule, nano-particle 15, a solid material or a fluid with magnetic components) is in the neighborhood of the conductors 12, it develops a magnetic moment m indicated by the field lines 16 in FIG. 2. In the operation mode shown in FIG. 2, only the conductor 12 on the left hand side is activated (that is a current flows through this conductor 12 along the positive y-axis), whereas the conductor 12 on the right hand side is deactivated (that is no current flows through this conductor 12).

The magnetic moment m then generates dipolar stray fields, which have in-plane magnetic field components 17 at the location of the sensor 11. Thus, the nano-particle 15 deflects the magnetic field 14 into the sensitive x-direction of the sensor 11 indicated by arrow 13 (FIG. 2). The x-component of the magnetic field Hx which is in the sensitive x-direction of the sensor 11, is sensed by the sensor 11 and depends on the number of magnetic nano-particles 15 and the conductor current Ic.

For further details of the general structure of such sensors, reference is made to WO 2005/010542 and WO 2005/010543.

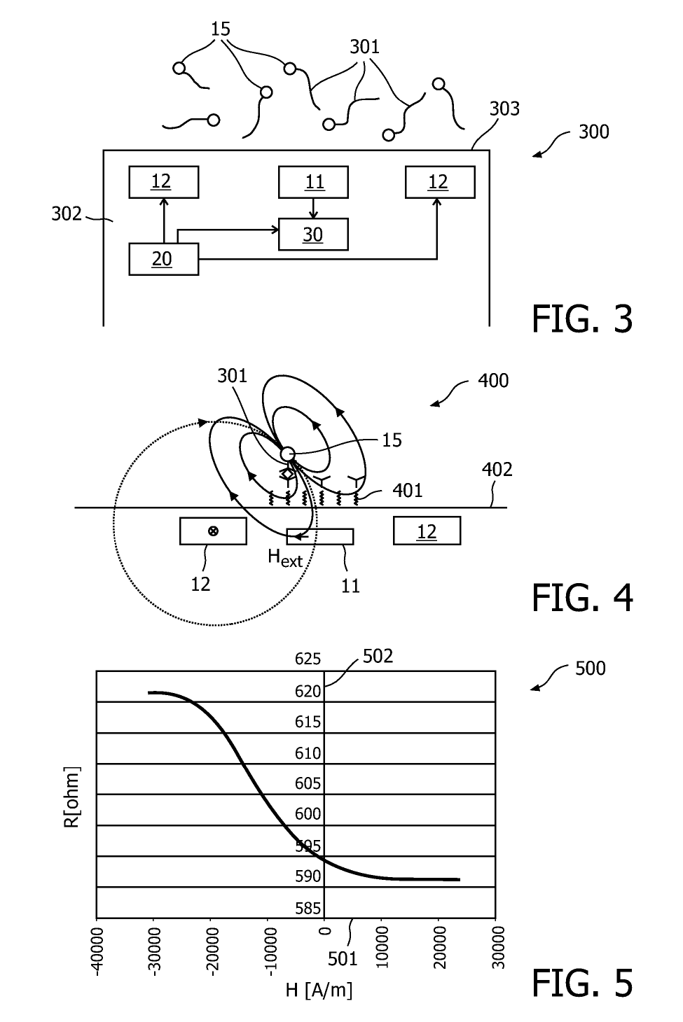

Reference numeral 20 in FIG. 1 and FIG. 2 illustrates a control unit coordinating the operation mode of the sensing unit 11 and of the magnetic field generator elements 12. A combining unit 30 combines the sensor signals detected by the GMR sensor 11 in different activation modes of the wires 12. Embodiments for such a control entity 20 and such a combining unit 30 will be explained below referring to FIG. 3 to FIG. 21B.

In the following, referring to FIG. 3, a magnetic sensor device 300 according to an exemplary embodiment of the invention will be explained.

The magnetic sensor device 300 is adapted for sensing beads or other magnetic nanoparticles 15 attached (for instance via linker molecules) to DNA strands 301 to be actually detected. The magnetic sensor device 300 comprises a magnetic field generator unit formed by two separate magnetic wires 12 and adapted for generating a plurality of different magnetic field configurations assigned to a plurality of different magnetic excitation states of the magnetic particles 15. In a first magnetic field configuration, the magnetic wire 12 shown on the left hand side of FIG. 3 is activated and the magnetic wire 12 shown on the right hand side of FIG. 3 is deactivated. In a second operation state, only the magnetic wire 12 shown on the right hand side of FIG. 3 generates a magnetic field and is therefore activated, whereas the magnetic wire 12 shown on the left hand side of FIG. 3 is deactivated thereby not generating a magnetic field in this operation state.

The activation and deactivation states of the magnetic wires 12 are controlled by a control unit 20, like a CPU (central processing unit).

Furthermore, a GMR sensing unit 11 is provided for sensing a plurality of detection signals influenced in a characteristic manner by the magnetic particles 15 in the different magnetic field configurations, depending on their concentration.

A combining unit 30 having processing and/or memory capabilities or resources may have access to algorithms for evaluating the detected signals, and may combine the plurality of signals to thereby derive information indicative of the presence of the magnetic particles 15. The combination unit 30 combines the plurality of signals to thereby stabilize a detection gain factor, as will be explained below in more detail.

As can further be taken from FIG. 1, the components 11, 12, 20 and 30 are integrated in a semiconductor substrate 302. The beads 15 attached to the biological molecules 301 are provided close to a main surface 303 of the substrate 302, along which main surface 303 the magnetic wires 12 are aligned.

The biosensor 300 may be part of an array of a plurality of such sensors (for instance one hundred) which may be integrated in a common substrate 302. The sensor principle may be based on the detection of super paramagnetic beads and may be used to simultaneously measure a concentration of a large number of different biological molecules (for instance proteins, DNA) in a solution (for instance blood). This may be achieved by attaching super paramagnetic beads 15 to the target molecules 301, magnetizing this bead 15 using an applied magnetic field and using a Giant Magnetoresistance (GMR) sensor 11 to detect the stray field of the magnetic beads 15.

FIG. 4 is an illustration 400 of an integrated excitation.

Auxiliary molecules 401 are immobilized on a surface 402 of the biosensor shown in FIG. 4, and after a hybridization of the biological molecules 301 having attached the beads 15, the presence or absence of the beads 15 may be detected using the magnetic wires 12 and the GMR sensor 11.

A current flowing in the wire 12 generates a magnetic field which magnetizes a super paramagnetic bead 15. The stray field from the super paramagnetic bead 15 introduces an in-plane magnetization component Hₑₓₜ in the GMR sensor 11, which results in a resistance change ΔR_{GMR}(Hₑₓₜ).

FIG. 5 shows a diagram 500 having an abscissa 501 along which the field H is plotted. Along an ordinate 502 of the diagram 500, the resistance R is plotted.

Thus, FIG. 5 shows the GMR resistance as a function of the magnetic field Hₑₓₜ in the sensitive layer of the GMR stack. The GMR sensitivity s_{GMR}=dR_{GMR}/dHₑₓₜ is not constant but depends on Hₑₓₜ. As mentioned above, SGMR and therefore the effective gain of the bio measurement is also sensitive to non-controllable parameters.

By applying a sensor gain stabilization algorithm during the actual measurement, artifacts arising from the discussed effects may be efficiently suppressed according to an exemplary embodiment of the invention.

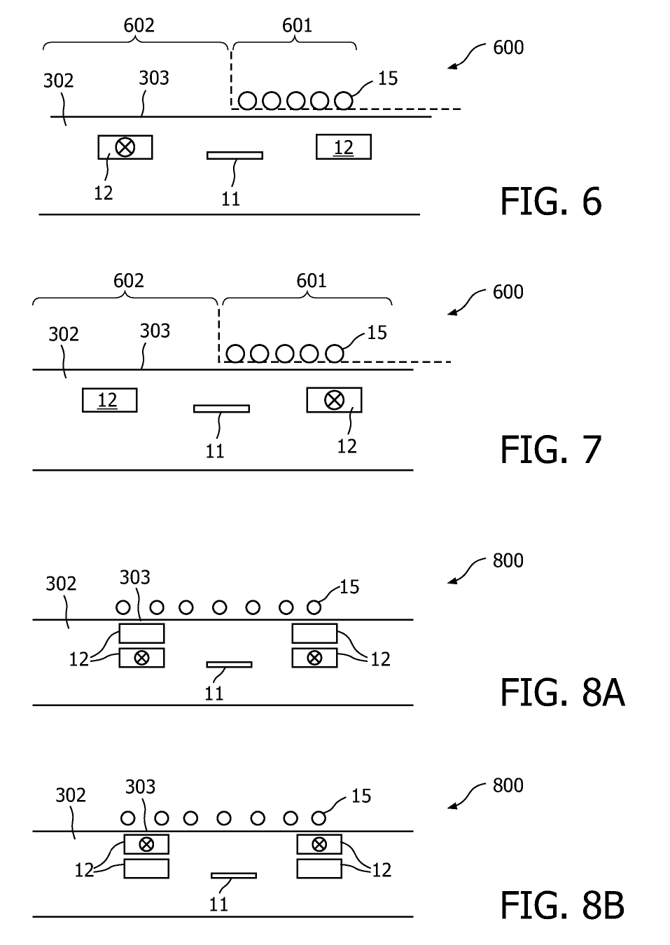

In the following, referring to FIG. 6, a magnetic sensor 600 according to an exemplary embodiment of the invention will be explained.

In the embodiment of FIG. 6, a switch between different excitation states may be performed.

The surface coverage of the beads 15 is limited to one half 601 of the sensor 600, whereas a second half 602 is free of beads 15. The excitation field is switched continuously between two states:

The first state is shown in FIG. 6, in which the left magnetic wire 12 is activated by current, whereas the right magnetic wire 12 is deactivated by the absence of a current.

In the state on FIG. 6, the detected GMR voltage may be simplified to

u₁=s_{GMR}{H_{MXT1}+H_{B1}}

In this equation, s_{GMR} is the sensitivity of the GMR sensor 11, H_{MXT1} is the magnetic crosstalk field given by the geometry of the sensor 600, and H_{B1} is the stray field from the magnetic beads 15 on the surface 303.

FIG. 7 shows the same biosensor 600 in a second operation state, in which the left magnetic wire 12 is deactivated and the right magnetic wire 12 is activated by a current flow.

In the second operation state shown in FIG. 7, the GMR voltage is

u₂=s_{GMR}{H_{MXT1}+βH_{B1}}

where the constant factor β expresses the change in the field from the beads 15 compared to the first state shown in FIG. 6. That factor β is determined by the geometry of the sensor 600 and may be calibrated prior to the actual measurement, for instance measuring the response on bead 15 sediment on the surface 303.

Then the weighted difference of the observed signals in both states may be calculated:

u₂−βu₁=s_{GMR}{H_{MXT1}+βH_{B1}}−βs_{GMR}{H_{MXT1}+H_{B1}}=s_{GMR}(1−β)H_{MXT1}

By calculating

s_{GMR}=(βu₁−u₂)/[(β−1)H_{MXT1}]

this value may be used to normalize or stabilize the detection gain. Prior to the actual bio-measurement, SGMR H_{MXT1} may be calibrated without beads 15.

By adding more excitation states (for instance both wires 12 activated), and more excitation wires (that is to say a larger number than two), more information may become available for calculating s_{GMR}, allowing to further increase accuracy.

Due the symmetrical geometry of the sensor 600, it may be assumed in proper approximation that the magnetic crosstalk in both states (FIG. 6, FIG. 7) is the same. When this assumption appears to be not valid, an additional constant (for instance calibrated prior to the measurements) may correct for this.

The embodiment shown in FIG. 6 and FIG. 7 is not limited to the appearance of beads 15 strictly on one half 601 of the sensor 600. Any well-controlled deviation from a homogeneous surface density is possible, for instance a gradual decrease of surface density is a function of the position.

A gradual increase of the surface height with respect to the sensor may effectively reduce the effect of beads on one side of the sensor, because they are further away from the sensor, and may avoid the use of a steep border between left and right. More generally speaking: there is no need for a sharp distinction between left and right.

In the following, referring to FIG. 8A, FIG. 8B, a biosensor 800 according to an exemplary embodiment will be explained.

In this embodiment, a switch between wires 12 at different positions in a direction perpendicular to a main surface 303 is performed.

According to this embodiment, additional current wires 12 are located at different vertical positions and are used to vary the relation between the internal crosstalk and the beads 15 signal.

FIG. 8A, FIG. 8B show a vertical stack of field generating current wires 12. In FIG. 8A, the bottom wires 12 are activated, whereas in FIG. 8B, the top wires 12 are activated.

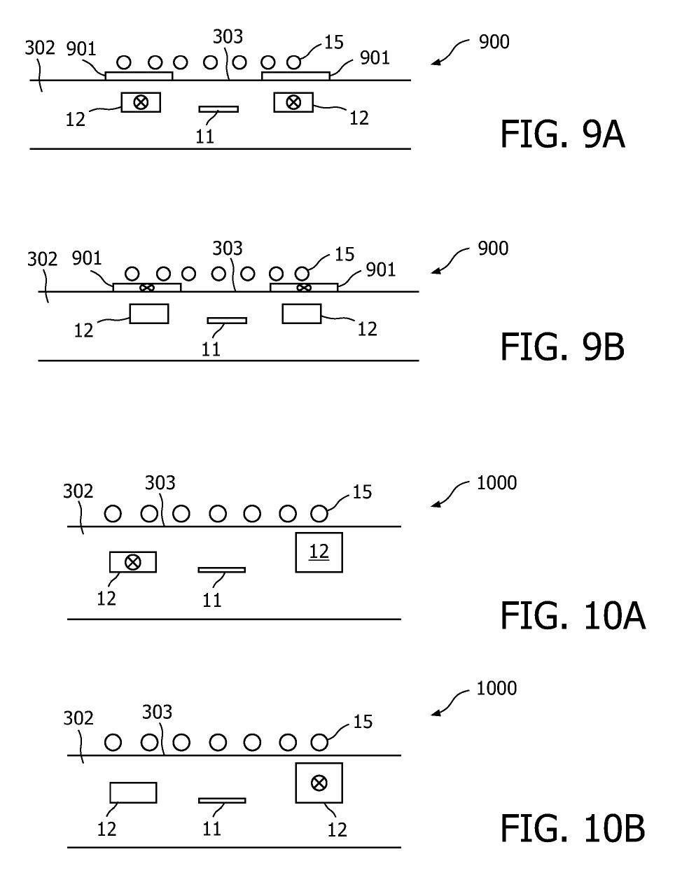

According to another exemplary embodiment shown in FIG. 9A, FIG. 9B, a biosensor 900 is provided on which a patterned gold layer is provided as magnetic field generator wires 901. Such a gold (Au) layer is provided in many cases on top of a biosensor, like in the case of the biosensor 900.

In FIG. 9A, the bottom wires 12 integrated within the substrate 302 are activated, and the patterned gold layer 901 deposited on the top of the sensor 900 surface 303 is deactivated. In FIG. 9B, the top gold wires 901 are activated, and the buried magnetic wires 12 are deactivated.

In the first stage shown in FIG. 9A, the detected GMR voltage may be simplified expressed as

u₁=s_{GMR}{H_{MXT1}+H_{B1}}

where s_{GMR} is the sensitivity of the GMR sensor 11, H_{MXT1} is the magnetic crosstalk given by the geometry of the sensor 900, and H_{B1} is the signal from the magnetic beads 15 on the surface 303.

In the second state shown in FIG. 9B, the GMR is voltage is

u₂=s_{GMR}{αH_{MXT1}+βH_{B1}}

Here, the constant factors α and β express the change in magnetic crosstalk and bead signals respectively compared to the first state shown in FIG. 9A. Said factors are determined by the geometry of the sensor 900 and may be calibrated prior to the actual measurement.

Then the weighted difference of both measurements is calculated:

βu₁−u₂=βs_{GMR}{H_{MXT1}+H_{B1}}−s_{GMR}{αH_{MXT1}+βH_{B1}}=s_{GMR}(β−α)H_{MXT1}

By using

s_{GMR}=(βu₁−u₂)/[(β−α)H_{MXT1}]

the gain of the detector 900 may be stabilized or normalized.

The factors α and β may be determined by the geometry of the sensor 900 and may be calibrated prior to the actual measurement, for instance by measuring for both states the magnetic crosstalk without beads 15 and for both states the sensor 900 response on beads 15 sediment on the surface.

Additional information may be achieved by adding more actuation states and/or more field generating wires 12, 901.

In this configuration, beads 15 within a few micrometers in a bulk above the sensor surface 303 may affect the stabilization process. This is because of a different z-position of the excitation wires 12, 901. Removal of said beads 15 above the sensor 900 during stabilizing may avoid or suppress this effect.

In the following, referring to FIG. 10A, FIG. 10B, a magnetic sensor device 1000 according to an exemplary embodiment will be explained.

In the embodiment shown in FIG. 10A and FIG. 10B, asymmetric wire dimensions are used. For instance, the excitation wires 12 may have different heights in a direction perpendicular to the main surface 303 of the substrate 301. In FIG. 10A, the smaller dimensioned magnetic wire 12 shown at the left hand side is activated, whereas the larger dimensioned magnetic wire 12 shown on the right hand side of FIG. 10A is deactivated. In FIG. 10B, the activation states of the wires 12 are reversed.

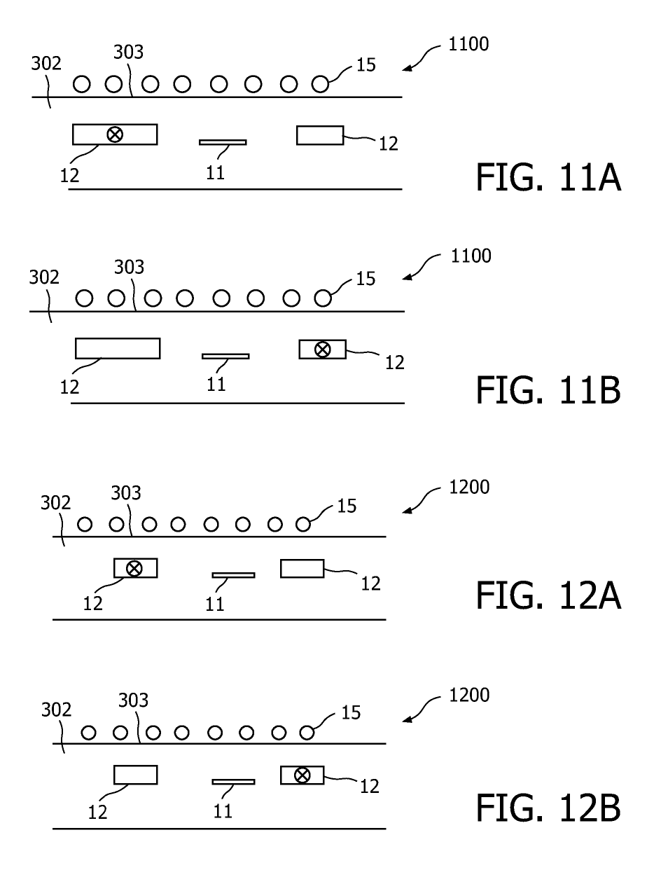

FIG. 11A and FIG. 11B show a magnetic sensor device 1100 having magnetic wires 12 with different dimensions in width, that is to say in a direction which is parallel to the surface plane 303.

In FIG. 11A, the left wire 12 is activated and the right wire 12 is deactivated, whereas in FIG. 11B the left wire 12 is deactivated and the right wire 12 is activated.

In the following, referring to FIG. 12A and FIG. 12B, a magnetic sensor device 1200 will be explained which is based on an asymmetric GMR sensor 11 positioning.

As can be taken from FIG. 12A and FIG. 12B, asymmetry is achieved by displacing the GMR sensor 11 in the x-direction, that is to say in a direction from the left hand side to the right hand side in the paper plane of FIG. 12A, FIG. 12B. This x-axis is also parallel to the plane of the main surface 303 of the substrate 301.

In FIG. 12A, the left magnetic wire 12 is activated, whereas the right wire 12 is deactivated. In FIG. 12B, the activation states of the two wires 12 is vice versa.

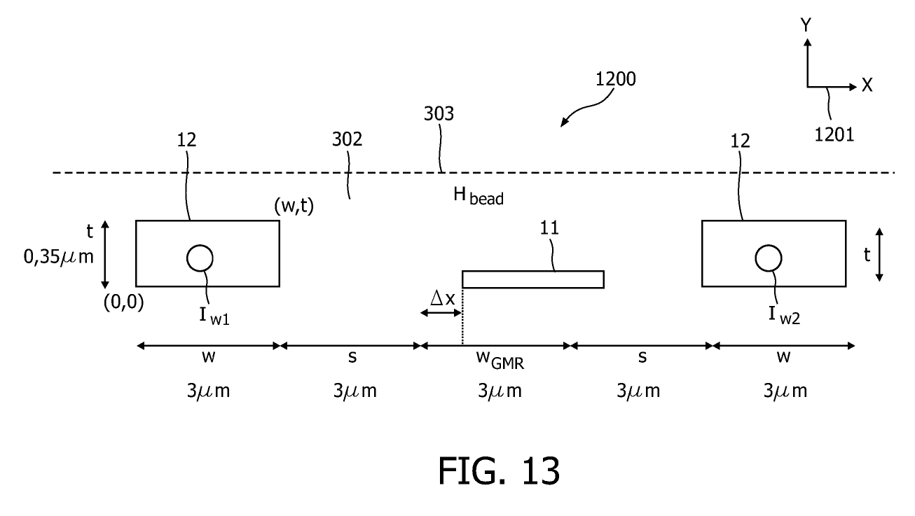

The working principle and the calibration procedure in the embodiment shown in FIG. 12A FIG. 12B will be explained in the following, referring to FIG. 13.

FIG. 13 is a detailed cross-section of the sensor 1200.

Here, the GMR sensor 11 is displaced over a distance Δx across the x-axis 1201 What now follows is an analysis of the GMR signals in the two excitation states shown in FIG. 12A, FIG. 12B.

Next, the first excitation state will be explained, that is to say a state in which the wire 12 shown on the left hand side of FIG. 13 is activated and the wire 12 shown on the right hand side of FIG. 13 is deactivated.

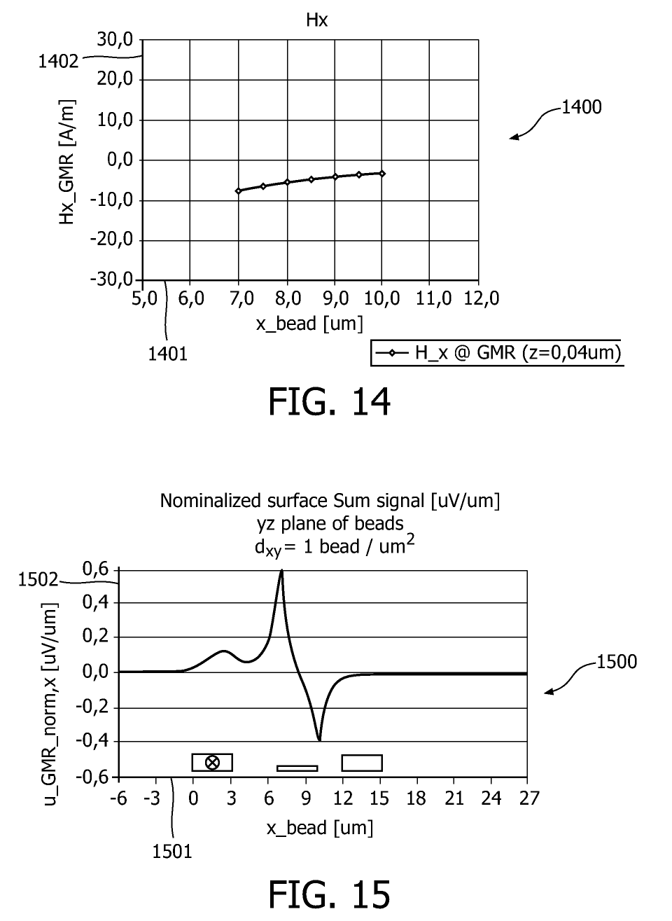

FIG. 14 shows a diagram 1400. Along an abscissa 1401 of the diagram 1400, the x-position is plotted. Along an ordinate 1402, Hx of the GMR sensor 11 is plotted. In other words, the in-plane magnetic crosstalk field in the sensitive layer of the GMR sensor 1200 is calculated without the presence of the beads 15.

The in-plane magnetic crosstalk field in the sensitive layer of the GMR as a function of the x-position is thereby shown in FIG. 14, induced by single wire, I_{wire,1}=10 mA.

By averaging the crosstalk field over the width of the GMR and substituting I_{GMR}=1 mA and s_{GMR}=0.003 Ωm/A, the crosstalk GMR voltage equals to u_{MXT1}=−14.78 μV.

The next step is to calculate the x-normalized GMR voltage induced by a row of beads 15 along the y-axis having a unit row width, as a function of the x-position of said row at the sensor surface (z=0.64 μm).

The result is plotted in FIG. 15.

The diagram 1500 illustrates an x-normalized GMR voltage on an ordinate 1502 in dependence of the x-position plotted along an abscissa 1501.

Therefore, FIG. 15 illustrates the x-normalized GMR voltage (μV/μm) at 1 bead/μm² uniform surface density, 130 nm NanoMag beads, I_{GMR}=100 μm (s_{GMR}=0.003 μm/A), Iₛₑₙₛₑ=1 mA, I_{Wire,1}=10 mA.

The curve shown in FIG. 15 can be considered as a “spatial surface impulse response” function u_{norm,x}(x). Under the assumption of a uniform bead distribution of 1 beads/μm² across the surface, the GMR response from the beads equals to

$${u}_{B 1} = {\int }_{- ∞}^{∞} {u}_{GMR , norm , x} ( x ) d x = 0.75 μV$$

The total GMR signal in the first state shown in FIG. 12A equals

u₁=u_{MXT1}+u_{B1}=−14.03 μV.

In the following, the second state with both wires 12 activated will be explained.

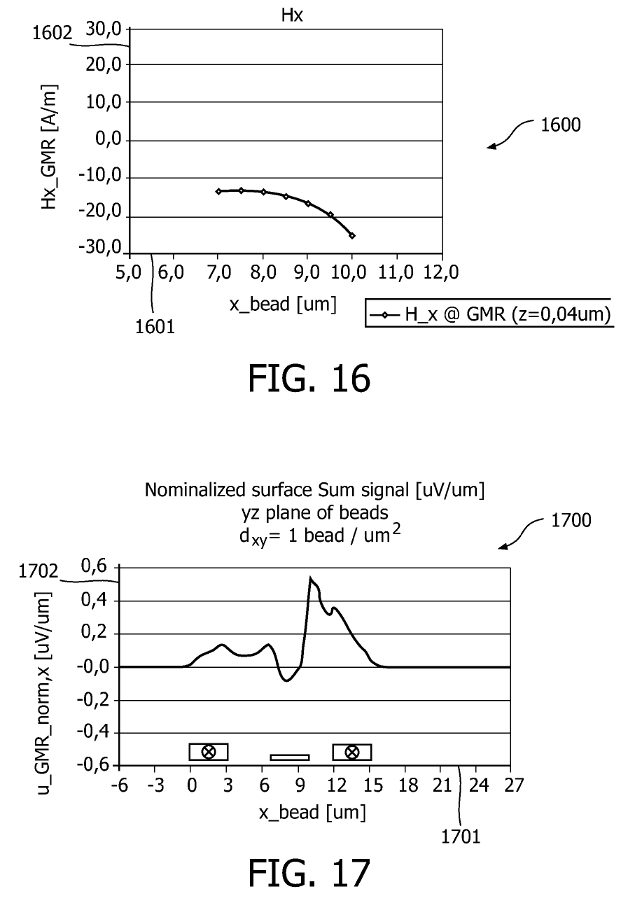

The magnetic crosstalk in the second state, when both wires 12 are activated, is plotted in FIG. 16.

FIG. 16 illustrates a diagram 1600 having an abscissa 1601 along which the x-position is plotted in μm. Along an ordinate 1602 of the diagram 1600, the field is plotted in A/m.

Therefore, FIG. 16 illustrates the in-plane magnetic crosstalk field in the sensitive layer of the GMR as a function of the x-position, induced by a single wire, I_{wire,1}=I_{wire,2}=10 mA.

This is caused by the fact that the second wire 12 (shown on the right hand side of FIG. 13) is closer to the GMR sensor 11 than the first wire 12 shown on the left hand side of FIG. 13.

FIG. 17 shows a diagram 1700 having an abscissa 1701 along which the x-position is plotted, and along an ordinate 1702 the sensor voltage is plotted in μV/μm.

FIG. 17 illustrates the response to the beads 15 at the surface 303, and illustrates the x-normalized GMR voltage in μV/μm at 1 bead/μm² uniform surface density, 130 nm NanoMag beads, I_{GMR}=100 μm (s_{GMR}=0.003 Ωm/A), Iₛₑₙₛₑ=1 mA, I_{wire,1}=I_{wire,2}=10 mA.

The GMR voltage from the beads 15 equals

$${u}_{B 2} = {\int }_{- ∞}^{∞} {u}_{GMR , norm , x} ( x ) d x = 2.18 μV$$

and

u₂=u_{MXT2}+u_{B2}=−45.85 μV.

Now the factors α and β will be defined, which express the ratio between the magnetic crosstalk and the bead signal in the second state and in the first state, hence

α=u_{MXT2}/u_{MXT1}=3.25

β=u_{B2}/u_{B1}=2.92

From said factors α and β, also the absolute magnetic gain may be calculated or derived.

Next, the calibration of the factors α and β will be explained.

The theoretical value of α and β are influenced by production tolerances at the sensor, which makes calibration steps prior to the bio-measurement likely to be necessary. What follows is a detailed description of an embodiment for such an optional calibration:

Factor α may be calibrated and determined prior to the bio-chemical reaction by measuring the sensor responses without beads.

u_{1,α}=u_{MXT1},u_{2,α}=αu_{MXT1}, hence α=u_{MXT2}/u_{MXT1}

Here, u_{1,α} and u_{2,α} are measured during a very short time in order to be sure that gain variations are neglectable. Because of the short measuring time, the signal-to-noise ratio may be poor. Therefore, the calculated α values may be averaged to achieve an acceptable signal-to-noise ratio.

The factor β may be calibrated from the sensor response to a bead sediment or immobilization, probably on, for instance, a reference sensor.

When it is assumed that

u_{1,β}=u_{MXT1}+u_{B1}

and

u_{2,β}=αu_{MXT1}+βu_{B1}

then factor β is equal to

β=(u_{2,β}−αu_{MXT1})/(u_{1,β}−u_{MXT1})

To avoid gain variations during calibration, u_{1,β} and u_{2,β} may be measured during a very short time after which the calculated β values are averaged. It is remarkable that the β calibration does not require knowledge about the bead concentration.

As already mentioned, for estimating β for calibration purposes, beads may be sedimented or immobilized on a reference sensor. However, it may be possible to omit such a reference sensor and to use the actual sensor for estimating β. The immobilized beads may then be removed after calibration. For instance, the beads may be washed away by a laminar flow or pulled away by a magnetic field, produced by e.g. an external magnet.

Next, gain calibration during the biochemical measurement will be explained.

By continuously measuring the detector signals and the two excitation states, the relative gain with respect to the initial value at the time that the biochemical reaction started may be calculated as follows.

At t=0, when the biochemical reactions starts, no beads 15 are present on the sensor and

u₁(0)=G(0)u_{MXT1} [symbol] u_{MXT1}=u₁(0)/G(0)

where G(0) represents the gain factor t=0.

During the course of the reaction, beads 15 immobilize on the sensor, hence

u₁=G(t){u_{MXT1}+u_{B1}}

and

u₂=G(t){αu_{MXT1}+βu_{B1}}

By calculating

βu₁−u₂=G(t)(β−α)u_{MXT1} [symbol] G(t)/G(0)=(βu₁−u₂)/((β−α)u₁(0))

This represents the relative gain with respect to t=0 when the reaction has started.

G(t)/G(0) may be used in a feed-forward configuration to normalize the detection gain or in a feedback system to stabilize the gain by for instance controlling the sense- or excitation current amplitude.

The time between the two gain measurements is fast enough in many cases to follow the expected gain SGMR variations.

Furthermore, the gain measurement time is preferably short enough to a avoid gain fluctuations between the excitation state during the gain measurement.

As mentioned earlier, the two excitation states may be applied in frequency multiplexing measured simultaneously. Hence, the wire currents are

I_{wire1}=sin ω_{S1}t+sin ω_{S2}t

I_{wire2}=sin ω_{S2}t

In such an embodiment, again variations during the measurement interval will not affect the result wrongly, because the gain varies essentially for every state.

This method has the advantage that the measuring time may be longer. It produces an average gain at increased signal-to-noise ratio.

The allowed dissipation and the electro-migration limit constraints the maximum current at each frequency component in wire 1 by factor of two, which effect degrades the signal-to-noise ratio.

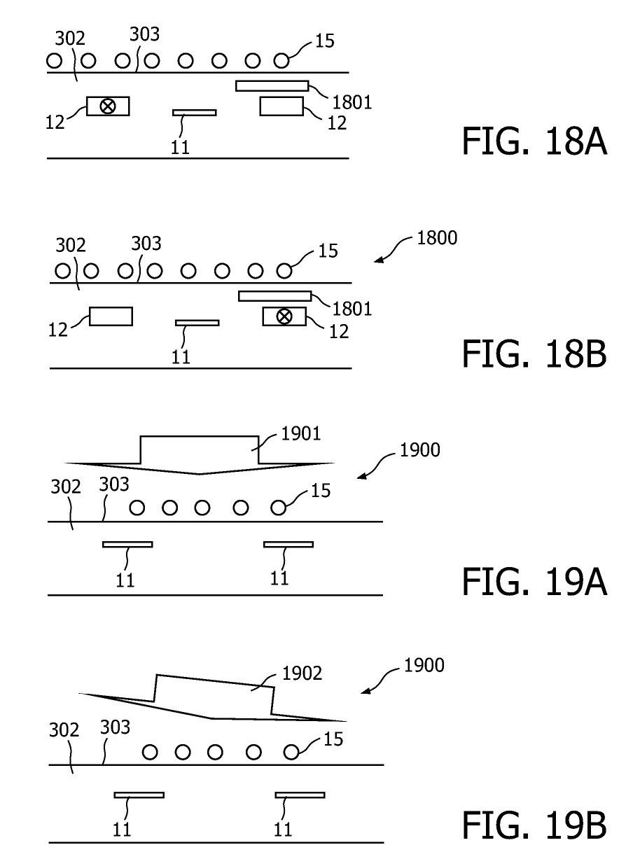

In the following, referring to FIG. 18A, FIG. 18B, a magnetic biosensor 1800 will be described according to an exemplary embodiment of the invention.

In this embodiment, a magnetic body 1801 is integrated in the silicon substrate 302 in an asymmetric manner with respect to magnetic wires 12.

The addition of such an entity 1801 having μᵣ≠1 changes the magnetic symmetry between the wires 12, which changes the signal crosstalk ratio for the two wires 12.

In FIG. 18A the left wire 12 is activated, whereas the right wire 12 is deactivated. In FIG. 18B, the left wire 12 is deactivated, and the right wire 12 is activated.

In the following, referring to FIG. 19A, FIG. 19B, a magnetic sensor device 1900 according to another exemplary embodiment of the invention will be explained.

In the embodiment shown in FIG. 19A, FIG. 19B, the magnetic field is generated by an external magnetic field source (not shown). Such an external magnetic field source may be, for example, an electromagnet or a static magnet.

In FIG. 19A, the external magnetic field 1901 has a first orientation, and in FIG. 19B, the external magnetic field 1902 has a second orientation and is tilted with respect to the first orientation.

In other words, in the embodiment of FIG. 19A, FIG. 19b, a magnetic biosensor 1900 is provided where the beads 15 are magnetized by an externally generated excitation field 1901, 1902. Two excitation states (see FIG. 19A, FIG. 19B) are achieved by tilting the external magnetic field 1901, 1902 in the in-plane plane of the GMR sensors 11.

The combination with any of the previous embodiments is of course easily possible.

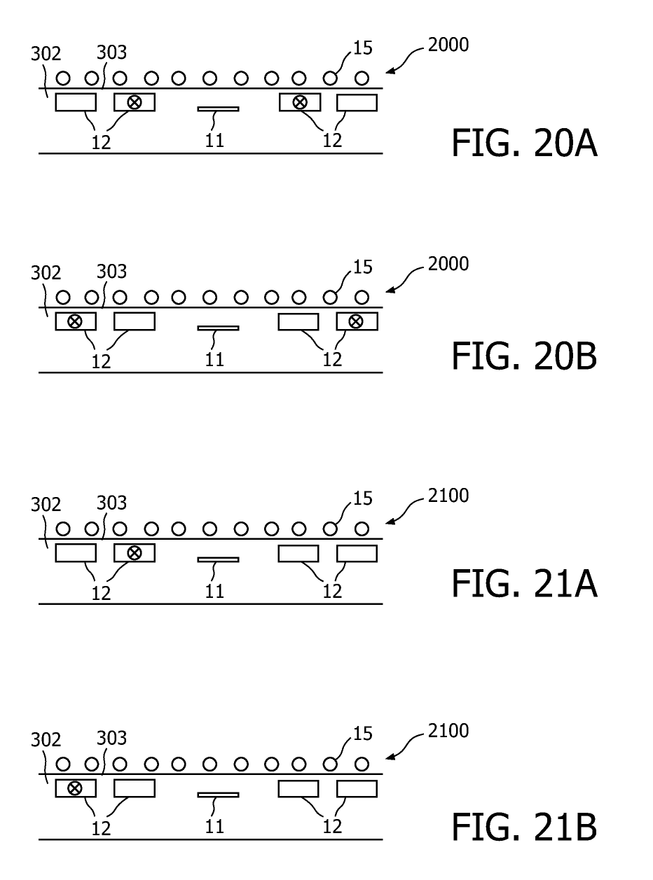

FIG. 20A, FIG. 20B show a magnetic biosensor device 2000 according to an exemplary embodiment of the invention in the two states, wherein multi planar excitation wires 12 are used.

In FIG. 20A, the inner wires 12 are activated. In FIG. 20B, the outer wires 12 are activated.

A further variation shown in FIG. 21A, FIG. 21B relates to a sensor device 2100 according to another exemplary embodiment of the invention.

In FIG. 21A, FIG. 21B, the advantage may be achieved that the demands on the bead surface density homogeneity are released, because of the small sensor area involved in the measurement.

In FIG. 21A, only one inner wire 12 is activated, and in FIG. 21B only one outer wire 12 is activated.

It should be noted that the term “comprising” does not exclude other elements or features and the “a” or “an” does not exclude a plurality. Also elements described in association with different embodiments may be combined.

It should also be noted that reference signs in the claims shall not be construed as limiting the scope of the claims.

1. A magnetic sensor device (300) for sensing magnetic particles (15), the magnetic sensor device (300) comprising
a magnetic field generator unit (12) adapted for generating a plurality of different magnetic field configurations assigned to a plurality of different magnetic excitation states of the magnetic particles (15);
a sensing unit (11) adapted for sensing a plurality of detection signals influenced by the magnetic particles (15) in the different magnetic field configurations;
a combining unit (30) adapted for combining the plurality of signals to thereby derive information indicative of the magnetic particles (15).

2. The magnetic sensor device (300) of claim 1,
wherein the magnetic field generator unit (12) is adapted for generating the plurality of different magnetic field configurations sequentially in time.

3. The magnetic sensor device (300) of claim 1,
wherein the magnetic field generator unit (12) is adapted for generating the plurality of different magnetic field configurations by frequency multiplexing.

4. The magnetic sensor device (300) of claim 2,
wherein the combination unit (30) is adapted for averaging a gain characteristic correlated with the plurality of signals.

5. The magnetic sensor device (300) of claim 1,
wherein the magnetic field generator comprises a plurality of magnetic field generator elements (12, 12).

6. The magnetic sensor device (300) of claim 5,
wherein the plurality of magnetic field generator elements (12, 12) are activable individually or in a groupwise manner for generating the plurality of different magnetic field configurations.

7. The magnetic sensor device (600, 1200) of claim 5,
wherein the sensing unit (11) is arranged symmetrically or asymmetrically with respect to the plurality of magnetic field generator elements (12, 12).

8. The magnetic sensor device (1000) of claim 5,
wherein the plurality of magnetic field generator elements (12, 12) have different dimensions.

9. The magnetic sensor device (300) of claim 5,
comprising a substrate (302) in which at least a part of the plurality of magnetic field generator elements (12, 12) is integrated.

10. The magnetic sensor device (300) of claim 9,
wherein the plurality of magnetic field generator elements (12, 12) integrated in the substrate (302) are arranged parallel to a main surface (303) of the substrate (302).

11. The magnetic sensor device (800) of claim 9,
wherein the plurality of magnetic field generator elements (12, 12) are integrated in the substrate (302) to be arranged vertically with respect to a main surface (303) of the substrate (302).

12. The magnetic sensor device (600) of claim 9,
adapted in such a manner that a predetermined spatial dependence of the magnetic particles (15) is adjustable above a main surface (303) of the substrate (302).

13. The magnetic sensor device (900) of claim 9,
adapted in such a manner that another part of the plurality of magnetic field generator elements (901, 901) is provided on a main surface (303) of the substrate (302).

14. The magnetic sensor device (1800) of claim 5,
comprising a magnetic body (1801) influencing the plurality of magnetic field generator elements (12, 12) in a plurality of different magnetic field configurations.

15. The magnetic sensor device (1900) of claim 1,
wherein the magnetic field generator unit is adapted for generating a plurality of different magnetic field configurations differing with regard to the magnetic field direction (1901, 1902).

16. The magnetic sensor device (300) of claim 1,
wherein the combination unit (30) is adapted for combining the plurality of signals to thereby stabilize a detection gain factor.

17. The magnetic sensor device (300) of claim 1,
comprising a switch unit (20) adapted for switching between the plurality of different magnetic field configurations.

18. The magnetic sensor device (300) of claim 1,
wherein the sensing unit (11) is adapted for sensing the magnetic particles based on an effect of the group consisting of GMR, AMR, TMR or Hall effect.

19. The magnetic sensor device (300) of claim 1,
wherein the combination unit (30) is adapted for combining the plurality of signals to thereby derive information indicative of a quantity of the magnetic particles (15).

20. The magnetic sensor device (300) of claim 1,
adapted for sensing magnetic beads (15) attached to biological molecules (301).

21. The magnetic sensor device (300) of claim 1,
adapted as a magnetic biosensor device.

22. The magnetic sensor device (300) of claim 1,
wherein at least a part of the magnetic sensor device (300) is realized as a monolithically integrated circuit.

23-27. (canceled)
